(19) United States
(12) Patent Application Publication
(10) Pub. No.: US 2021/0115588 A1
(43) Pub. Date: Apr. 22, 2021

(54) MOLECULAR BEAM EPITAXY SYSTEMS WITH VARIABLE SUBSTRATE-TO-SOURCE ARRANGEMENTS

(71) Applicant: Veeco Instruments Inc., Plainview, NY (US)

(72) Inventors: Richard Charles Bresnahan, Denmark Township, MN (US); Scott Wayne Priddy, Saint Louis Park, MN (US); William Colbert Campbell, III, Andover, MN (US); Mark Lee O'Steen, Centerville, MN (US); Stephen Gary Farrell, Minneapolis, MN (US)

(21) Appl. No.: 17/074,350

(22) Filed: Oct. 19, 2020

Related U.S. Application Data
(60) Provisional application No. 63/088,411, filed on Oct. 6, 2020.
(60) Provisional application No. 62/916,746, filed on Oct. 17, 2019.

(51) Int. Cl. C30B 23/00

(52) U.S. Cl. CPC C30B 23/005

(57) ABSTRACT

Systems and methods for providing controllable substrate-to-source arrangements in a Molecular Beam Epitaxy (MBE) system to selectively adjust a distance, orientation, or other geometric configuration as between the source(s) and substrate(s) used in epitaxial growth systems are described herein. It has been found that by controllably adjusting height, crucible type and angle, and other processing conditions, that extremely high thickness uniformity can be accomplished in epitaxially grown wafers.

### CROSS-REFERENCE TO RELATED APPLICATIONS

The instant application claims the priority benefit under the Paris Agreement of U.S. provisional application Ser. Nos. 62/916,746 and 63/088,411, the contents of which are hereby incorporated by reference in their entirety.

### TECHNICAL FIELD

The present disclosure relates generally to vacuum effusion techniques and equipment. Embodiments described herein relate to deposition of material by thermal evaporation of multiple sources, such as by Molecular Beam Epitaxy (MBE).

### BACKGROUND

Molecular Beam Epitaxy (MBE) can be used to deposit evaporated materials on a substrate. In the simplest version of this technology, a material is placed in a boat or crucible, which is positioned in a vacuum chamber. Heat is applied to the material to cause evaporation or sublimation of the material. The resulting beam of material is collected at a target, or substrate, within the same vacuum chamber and heated to an appropriate temperature. If the deposition rate of the materials and the substrate temperature are correct then epitaxial growth can occur (i.e., growth of single crystal films).

MBE techniques have been improved over the last several decades to use multiple sources of material, resulting in more complex materials such as semiconductors that form when the materials combine on the substrate. MBE has been used to form, for example gallium arsenide (GaAs) and aluminum arsenide (AlAs) materials epitaxially. The materials formed in a single MBE run can vary, to create multi-layer structures usable as diodes, field-effect transistors, and other useful structures.

MBE systems using source material delivered off-axis are described generally in U.S. Pat. No. 5,788,776 to Colombo, for example. These sources can be directed using a horn-shaped tube to manage the direction with which evaporated material travels, as described in U.S. Pat. No. 5,820,681 (Colombo et al.). State-of-the-art MBE devices for making such structures include VEECO® GEN20™ MBE systems, VEECO® GEN200™ MBE systems, and VEECO® GEN2000™ MBE systems, for example. Such systems can include complex wafer-handling and high throughput, with long run times.

In general, it is desirable to ensure the greatest possible uniformity in thickness of the deposited materials, such as wafers, created by an MBE system. Existing solutions to this technical challenge include selectively aiming the beams of evaporated or sublimated materials to prevent peaks or valleys in the final product. Additionally, various modifications to the crucible conditions (such as temperature of operation, how the material is filled, or nozzle design) can affect the level of uniformity in the final product. U.S. Pat. No. 4,646,680 to Maki, for example, describes a conical member that increases the thermal impedance between the melt surface and the interior of the MBE system to reduce the flux transient and increase the uniformity of the molecular beam over the area being processed. Other proposed solutions for enhancing uniformity involve rotating the substrate continuously relative to the sources within the vacuum, thus evening out any non-uniformities, as described in U.S. Pat. No. 4,945,774 to Beard et al.

Thickness uniformity is becoming of greater importance as ever-thinner layers of materials are demanded in some technical fields. For example, creation of a vertical-cavity surface-emitting laser (VCSEL) requires making thinner and more precise layers than conventional counterparts. For VCSEL and other high-precision applications, some portion of a wafer made by MBE or other processes such as chemical vapor deposition (CVD) are acceptable, while others have insufficiently precise thicknesses. Areas of the wafer having insufficiently precise layer thicknesses must be either used in some less critical application or scrapped. It is therefore highly desirable for the percentage of usable wafer to be as high as possible, to avoid waste of reactor time and the precursor materials used to make such wafers.

Accordingly, there is a continuing need for even further improvements to the uniformity of the materials created by vacuum deposition techniques such as MBE systems.

### SUMMARY

Embodiments herein include devices, systems, and methods for providing controllable substrate-to-source arrangements in a Molecular Beam Epitaxy (MBE) system to selectively adjust a distance, orientation, or other geometric configuration as between the source(s) and substrate(s). Given the significant challenges in changing the setup and configuration of an MBE system operating in a rotational configuration under high vacuum and high temperature conditions, control of temperature of the MBE process has conventionally been the sole adjustment made to improve uniformity of wafers made with multiple types of source precursor materials. By using embodiments configured to vary the source-to-substrate arrangements of an MBE system, the uniformity of the final product can be unexpectedly enhanced by tuning both the temperature of the process reactor and the physical arrangements of the substrate(s) and source(s) such as the distance, the tilt of the source material crucibles, and/or crucible type for each of the materials used.

According to a first embodiment, a molecular beam epitaxy system includes a process chamber, and a plurality of ports arranged at a first end of the process chamber. Each of the plurality of ports configured to hold a source material. A heater is configured to heat each of the plurality of ports such that the source material corresponding to each of the plurality of ports is vaporized to form a plume. A substrate is disposed at a second end of the process chamber and arranged to receive the plume corresponding to each of the plurality of ports. A vertical height manipulator is coupled to the substrate and configured to selectively move the substrate to modify a distance between the plurality of ports and the substrate.

In various embodiments, the vertical height manipulator can be selected from the group consisting of a ball-screw drive, a rack-and-pinion gear drive, a pneumatic drive, a magnetic drive from outside the chamber, and a lever drive. The molecular beam epitaxy system can further include a controller. The controller can be configured to modify the distance between the plurality of ports and the substrate based upon a particular material arranged in any one of the plurality of ports. The controller can alternatively or conjunctively be configured to modify the distance between the plurality of ports and the substrate based upon a level of tilt of one of the plurality of ports. The controller can be configured to modify the distance between the plurality of ports and the substrate during processing to create a wafer having a thickness non-uniformity of less than 1% across the wafer, or based on a desired precursor material usage efficiency. The molecular beam epitaxy system can include a plurality of crucibles, each of the plurality of crucibles arranged in a corresponding one of the plurality of ports and each of the crucibles containing one of the plurality of source materials. At least one of the plurality of crucibles can be either asymmetric or symmetric.

According to another embodiment, a kit for modifying a molecular beam epitaxy system includes those components that can be used to add vertical shift capabilities to an existing reactor. In one embodiment, a vertical shift manipulator is included that can be coupled to the substrate of the molecular beam epitaxy system such that the substrate of the molecular beam epitaxy system is arranged at a variable distance from each of a plurality of ports, each of the ports having a corresponding source material. At least one controllable motor can be included that is configured to drive the vertical shift manipulator. The kit can further include software configured to drive the controllable motor for sequential deposition of multiple layers in the molecular beam epitaxy system.

The controller of the kit can be configured to drive the controllable motor based upon a particular material arranged in a port of the molecular beam epitaxy system. The controller can be configured to drive the controllable motor based upon a level of tilt of one of a plurality of ports of the molecular beam epitaxy system. The vertical height manipulator can be selected from the group consisting of a ball-screw drive, a rack-and-pinion gear drive, a pneumatic drive, a magnetic drive from outside the chamber, and a lever drive. The controller can be configured to modify the distance between the plurality of ports and the substrate during processing to create a wafer having a thickness non-uniformity of less than 1% across the wafer. In embodiments, the kit can include a replacement heater element as well, and a cryolid capable of receiving the heater.

According to another aspect, embodiments include a method for creating a wafer using a molecular beam epitaxy system. The method includes arranging a substrate in the molecular beam epitaxy system such that the substrate is mechanically coupled to a vertical shift manipulator. The method further includes arranging a plurality of material sources in the molecular beam epitaxy system, the plurality of material sources corresponding to precursor materials of the wafer. The method further includes driving the substrate, with the vertical shift manipulator, to a predetermined distance from a first one of the plurality of material sources. The method further includes depositing a first layer of the wafer from the first one of the plurality of material sources at the substrate. The method includes repeating the driving and depositing for each of the plurality of material sources to form one or more additional layers of the wafer.

Optionally, the method can include setting the predetermined distance for each of the first layer and the one or more additional layers based upon a desired thickness uniformity of the wafer. Additionally or alternatively, the predetermined distance for each of the first layer and the one or more additional layers may set based upon a desired material usage efficiency for the plurality of precursor materials. Additionally or alternatively, the predetermined distance for each of the first layer and the one or more additional layers can be set based upon both a desired thickness uniformity of the wafer and a desired material usage efficiency for the plurality of precursor materials. The methods described above are usable on the systems described above, or on the retrofitted systems that incorporate the kits described above.

The above summary is not intended to describe each illustrated embodiment or every implementation of the subject matter hereof. The figures and the detailed description that follow more particularly exemplify various embodiments.

### BRIEF DESCRIPTION OF THE DRAWINGS

Subject matter hereof may be more completely understood in consideration of the following detailed description of various embodiments in connection with the accompanying figures, in which:

FIG. 1A is a schematic view of a lid of a Molecular Beam Epitaxy (MBE) system, according to an embodiment.

FIGS. 1B-1E show plan views of four exemplary substrate holders that can be used in an MBE system as depicted in FIG. 1A.

FIGS. 1F-1G depict a partial views of a deposition chamber in accordance with embodiments of an MBE system as depicted in FIG. 1A.

FIG. 1H is a side cutaway view of a tilted source according to an embodiment.

FIG. 2 is an x-ray scan of a point on a wafer compared to the simulated data, showing excellent agreement.

FIG. 3 depicts five positions on a substrate where x-ray measurements were taken.

FIG. 4A depicts deposition thickness of a first material at each of the five points depicted in FIG. 3 as a function of substrate-to-source distance; and FIG. 4B illustrates the same data in a normalized format.

FIG. 5A depicts deposition thickness of a second material at each of the five points depicted in FIG. 3 as a function of substrate-to-source distance; and FIG. 5B illustrates the same data in a normalized format. FIG. 5C illustrates the flux uniformity for aluminum as a function of growth platen height.

FIG. 6A is a schematic view of flowpaths within a deposition chamber of an MBE system, according to an embodiment.

FIGS. 6B-6D depict partial view of embodiments of the flowpaths within a deposition chamber of an MBE system in which the substrate is selectively positioned at different distances relative to the materials sources.

FIG. 6E is a detailed view of a vertical-shift stage that is suitable for use with embodiments described herein.

FIG. 7 is a graphic depiction of the modeled deposition uniformity and material utilization for two different source-to-substrate distances as a function of the exponent, n, in cosⁿ(theta) flux shapes.

FIGS. 8A-8C depict crucibles that can be used within the MBE systems described herein.

FIG. 9 is a graphic depiction of the relationship of material uniformity to flux rate for a given crucible shape.

FIG. 10 is a graphic depiction of the deposition rate as a function of source operating temperature and amount of material loaded.

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION OF THE DRAWINGS

Embodiments described herein employ a variable distance between the substrate for deposition and the source material in a vacuum deposition system, such as a Molecular Beam Epitaxy (MBE) system. Conventionally, only temperature could be modified within an MBE system after epitaxy begins. This is due to the inherent difficulties in moving source material about within an ultra-high-vacuum environment.

Throughout this disclosure, the word “evaporated material” or “beam” are used to refer to sputtered, evaporated, or sublimated materials that can be used in MBE. It should be understood that the benefits described herein apply equally to these various modes of creating a source (or multiple sources) of material to be used in a vacuum deposition technique, process or equipment. Furthermore, throughout the application there are references to orientation or position in a reactor chamber. As used throughout this application, the word “vertical height,” “height,” or “distance” refer to the amount of distance between the MBE material supply and the location where it is deposited. Typically, multiple sources of precursor material (e.g., Al, As, or Ga, among others) are arranged in a circular pattern on one end of a reactor, while the material is deposited at the other end. Furthermore, conventionally (and due to the way in which plumes of MBE material form from heated precursor material) the material is evaporated at a gravitational bottom of the reactor and travels to a target at the top of the reactor. Therefore “bottom” and “top” may be used herein to refer to the ends on which the material is evaporated and the ends on which the material is deposited, respectively. It should be understood that in some configurations, these may not be exactly the gravitational top or bottom, and that there may be systems in which these are rotated or inverted from this conventional arrangement.

The terms “target,” “substrate,” “platen,” and “wafer” are all terms that refer generally to the area where the MBE material is deposited to cause epitaxial growth. Typically, a platen is coupled by some linking means to a motor such that it can be rotated to improve thickness uniformity of a deposited material. A wafer can be attached to the platen to form a substrate for deposition. One or more wafers can in turn be grown on the substrate of the material.

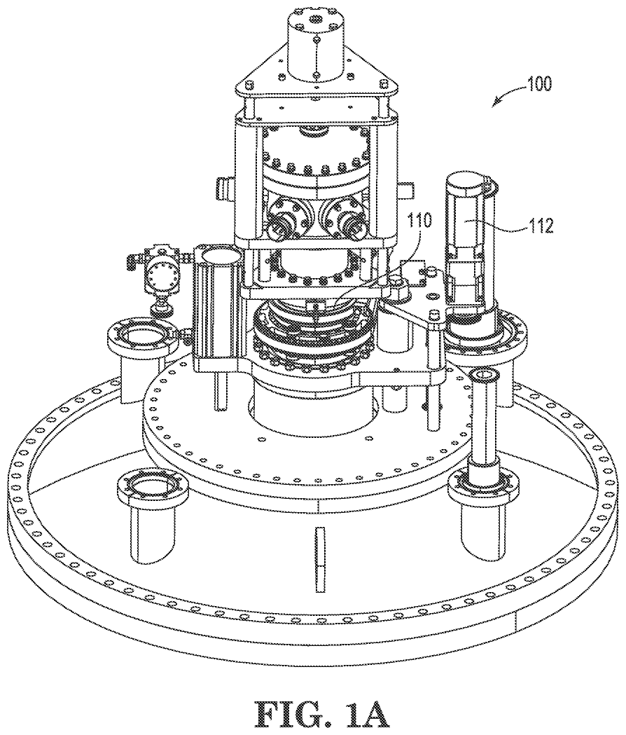

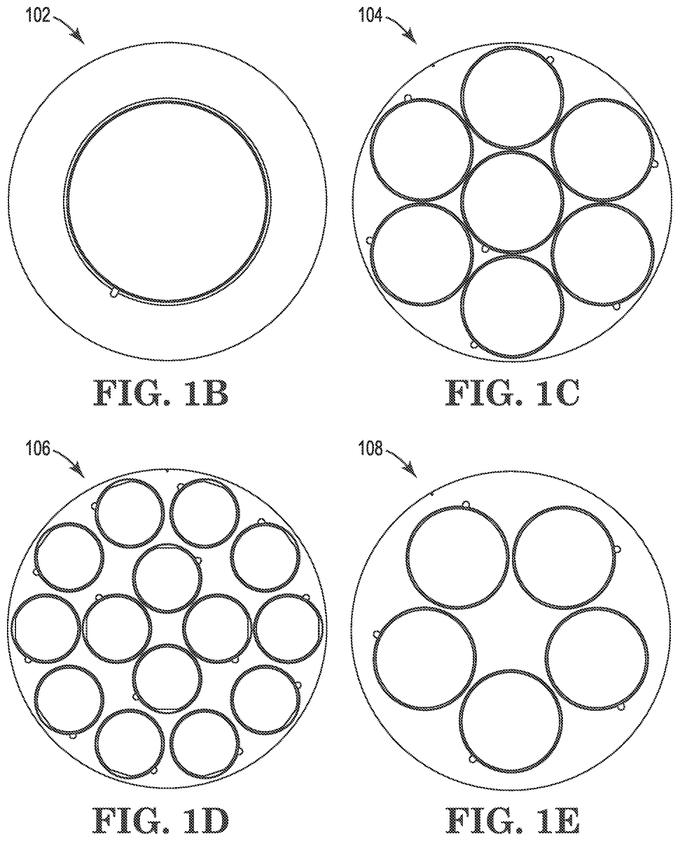

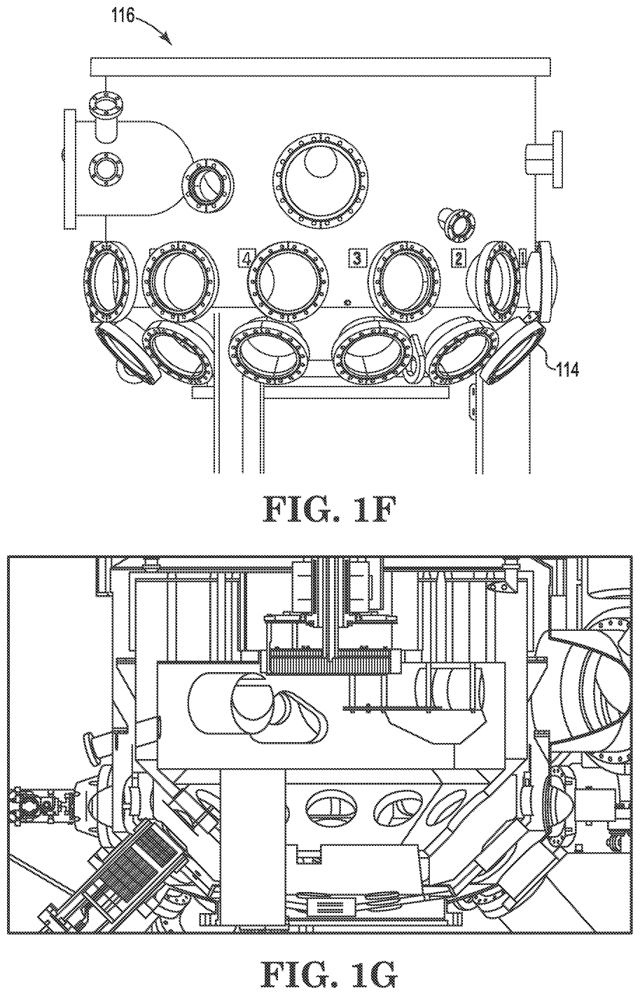

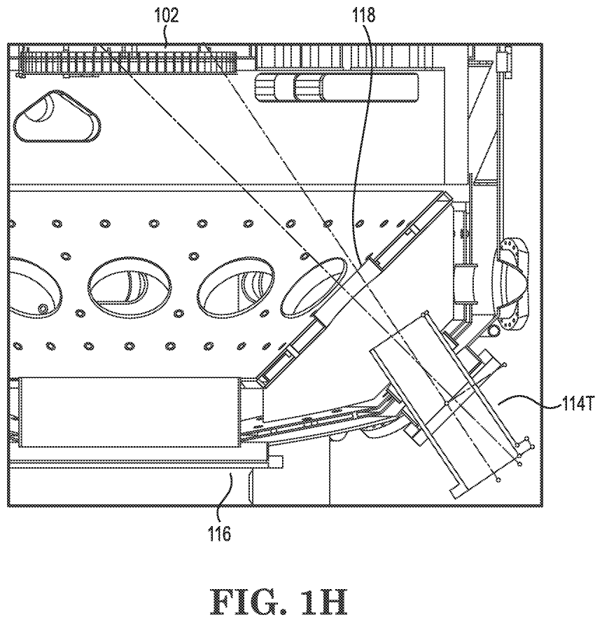

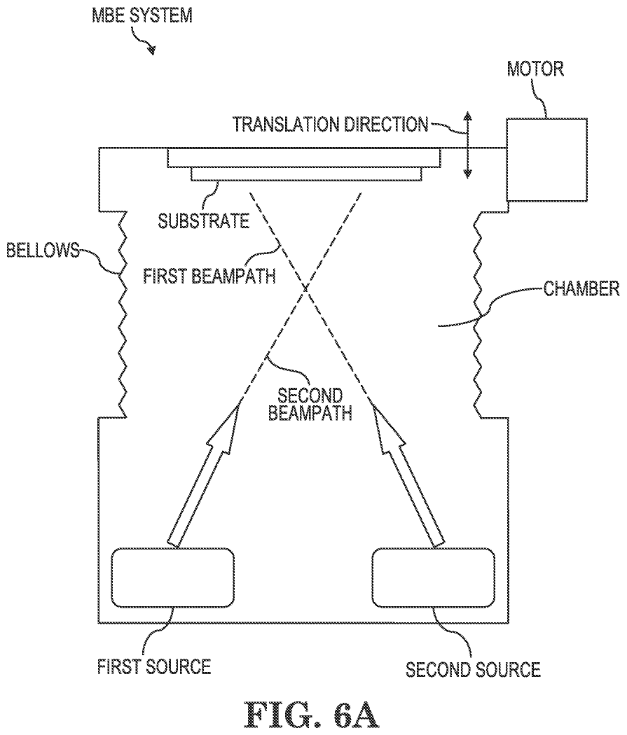

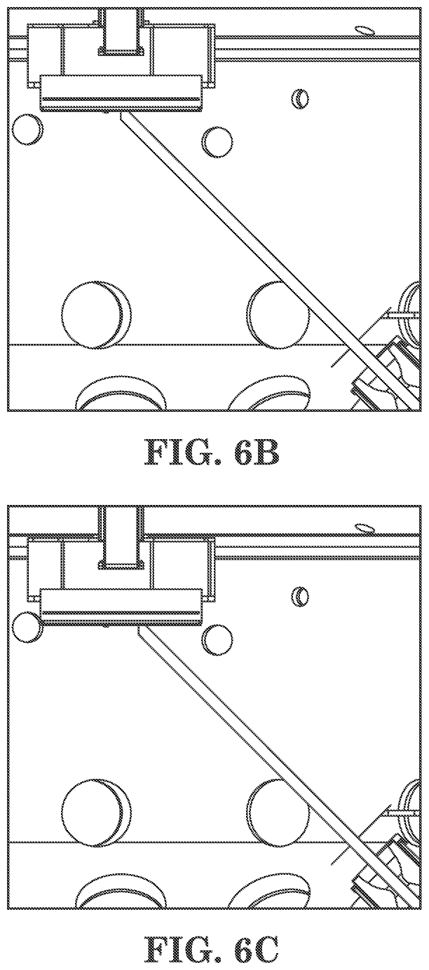

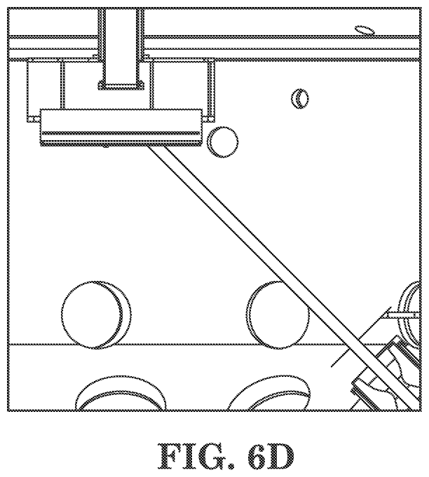

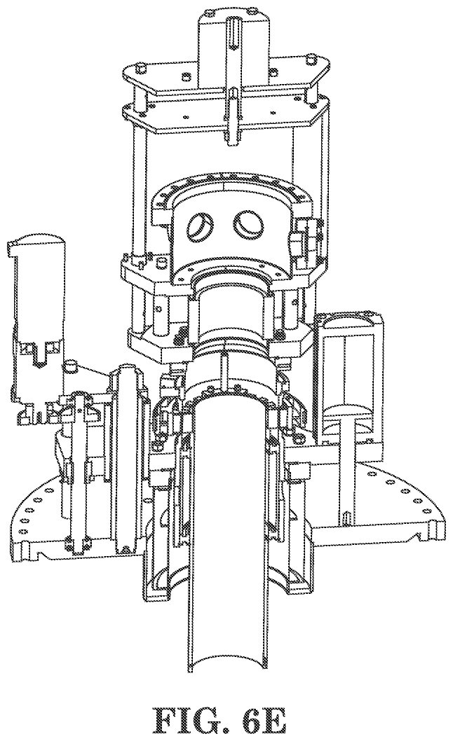

MBE Systems Most automated MBE systems deposit material on a downward facing substrate, such as the partial MBE system 100 shown in FIG. 1A. The position of the substrate (see FIG. 6) is set in the vertical direction and the sources of evaporated material (see FIG. 6) are aimed at or near the center of the substrate. With multiple similar sources arranged around the substrate it is possible to deposit or grow a compound material that has spatial uniformity as well as compositional uniformity.

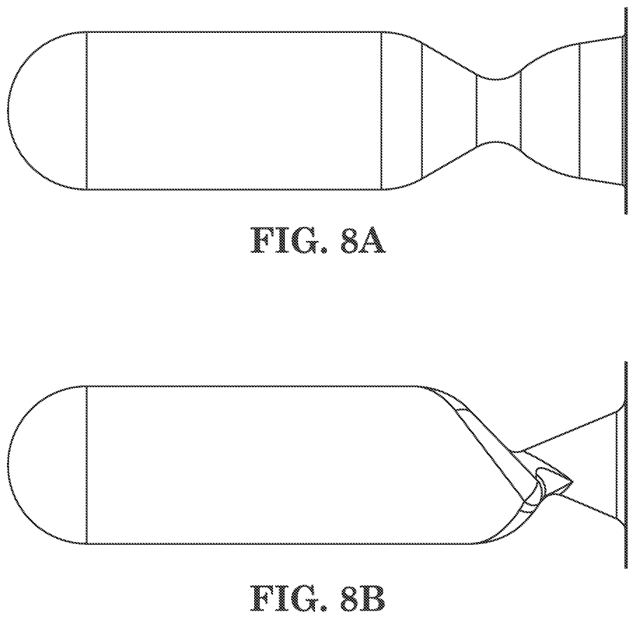

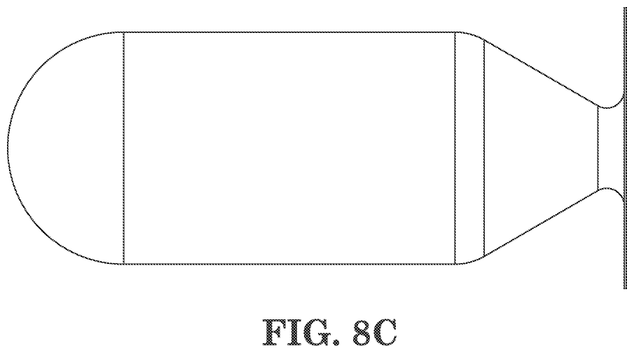

The flux shapes generated by various sources are different from different crucibles and sources. Some example crucible shapes are shown at FIGS. 8A-8C. For many reasons the crucible and diffuser plates used on different materials give slightly different flux patterns. Plumes can vary considerably in their shape and size and other characteristics based upon the reactor design, as described in M. A. Herman & H. Sitter, Molecular Beam Epitaxy, Fundamentals and Current Status, Springer Series in Materials Science 7 (Springer-Verlag 1989). Some considerations for crucible design and installation patterns can be found in US 2010/0159132, commonly owned by the Applicant and is incorporated by reference herein in its entirety. These plumes or vapor patterns created by the materials held in the crucibles can have optimal uniformity and distribution of deposition at different distances from source to target. To get better uniformity, the source material, crucible style, and orientation of the crucible in the processing chamber may all need to be considered. Non-optimal crucible style, orientation, or distance from the target can result in reduced quantity of material reaching the target substrate. This in turn reduces the utilization of the material which then requires a larger crucible or a shorter growth campaign. The desired flux shape can be dependent upon the materials being grown as well as the substrates used (e.g., substrates 102, 104, 106, and 108 as shown in FIGS. 1B-1E).

Moreover, the distance between source and target can be different based on the material used, the crucible used, or the processing conditions to such an extent that the distance appropriate for one material may be inappropriate for another. For example, in a GaAs system, the optimal distance for gallium may be different than the optimal distance for arsenic. Conventional systems do not have a fully satisfactory mechanism for addressing this difference, because source material is typically all loaded into an MBE reactor at the same (or very similar) fixed distances to the substrate. This problem is exacerbated when more materials are used, or in construction of multi-layer structures requires several interdigitated layers of different materials.

This problem has not been adequately addressed, or even identified, in conventional systems. For modern applications, thickness uniformity must be within about 1% of the target amount to be deposited. Standard non-uniformity for aluminum deposition is within about 10% of target, and use of conical crucibles reduces this to approximately 3% resulting in significant quantities of unusable wafers that must be scrapped or repurposed for use in less sensitive applications. Unfortunately, current approaches for reducing thickness non-uniformity to such as an extent that the total layer thickness remains less than 1% away from target across an entire wafer requires a careful coordination of crucible type, aiming point, distance from source to substrate, and processing conditions that in practice means use of multiple reactors (i.e., a different reactor for each material used).

Therefore, to accomplish the desired thickness uniformity using conventional mechanisms, the processing conditions must be manually changed and in some cases wafers are moved back and forth between processing reactors to add layers of different materials. These solutions require additional time and resources, introduce further potential for contamination of the sample or processing chambers as samples are moved about within a system, and generally slow down and increase both cost and complexity of forming a multi-layer MBE wafer.

### Variable Stage Systems

In various embodiments, the uniformity of material produced by a vacuum deposition system is enhanced by providing for the ability to change the vertical position of the substrate during a growth run, thereby allowing for the uniformity and utilization of the system to be optimized. As shown in an embodiment in FIG. 1A, a bellows 110 is positioned between the source and the susceptor thereof (while these internal components are not visible in FIG. 1A, a schematic view can again be seen in FIG. 6, as described below). A motor 112 is configured to expand or contract the bellows 110 by moving the top and bottom components containing the susceptor and/or sources, respectively, relative to one another, as desired.

In embodiments, the motor 112 could be replaced with a pneumatic system or other actuator that changes the height of the internal platen and, accordingly, the expansion or contraction of the bellows 110. Various supporting structures (not labeled in FIG. 1A) provide uniform support around the bellows 110 so that the expansion or contraction is straight up and down, rather than being torqued or canted by forces applied thereto. As a typical MBE system may be used at very low internal pressure, these supporting structures can be designed with sufficient robustness to counteract expected forces on the system during operation. As will be understood in light of the following description, it may be desirable to have a motor 112 or similar structure that is infinitely adjustable, or alternatively in some embodiments it may be sufficient (or even desirable) to have a system configured to change between a smaller number of preset heights that correspond to specific materials used in a deposition process. For example, a pneumatic system could be used to move the platen height (and correspondingly adjust the bellows 110) to between two and ten preset positions, or more advantageously for AlAs, GaAs, or GaAs systems between two and three positions.

As shown in FIGS. 1F and 1G, ports for sources 114 are arranged in a circle about a reactor base 116. Further description of the details and operation of the various components of a conventional MBE system without an ability to change the relative vertical positions of the substrate(s) and source(s) are described, for example in U.S. Pat. No. 5,788,776, the disclosure of which is hereby incorporated by reference.

As shown in FIG. 1H, tilted port 114T is used to provide deposited material to a substrate 102. As described above, tilted ports like 114T can be used to deposit material on a portion of the substrate 102 other than the center. As substrate 102 is rotated during deposition, this off-center deposition can result in enhanced thickness uniformity. The tilt of tilted port 114T affects which portions of the plume generated by the source therein pass through the opening 118. That is, for a highly tilted port 114T, the side of the plume will be aimed at the opening 118 while for a straight (or less tilted) port 114, the center of the plume will be aimed at the opening 118. Depending on which parts of the plume are the most uniform, there may be benefits to tilting or not tilting each port.

Additionally, it should be understood from FIG. 1H that the distance from source to wafer will vary based on the amount of tilt of tilted port 114T. That is, if the tilted port 114T is aimed at the radially outermost portion of the wafer 102 as shown, the source-to-target distance will be low. Aiming the port 114 at the center of the substrate, for example as shown in FIGS. 1F and 1G, results in a relatively longer distance from source to target. It should be understood that by tilting tilted port 114T down further and aiming at the other radially outer edge of substrate 102, an even longer source-to-target distance could be produced.

As shown in FIG. 1H, the tilt of the system indicated by the dashed lines can be adjusted so long as the plume generated by the material in the tilted port 114T is still directed through opening 118. Opening 118 is typically used to ensure only a portion of the plume that has a desired trajectory arrives at the substrate 102. The material that does not pass through opening 118 can be collected in a drip pan.

These processing conditions can be used to enhance thickness uniformity. During testing on commercially available reactors from VEECO INSTRUMENTS®, however, it was determined that in some circumstances this tilt alone will not result in the desired 1% or less thickness non-uniformity. It should be understood that tilted or straight ports can be used in combination with other features described herein to enhance overall deposited material uniformity.

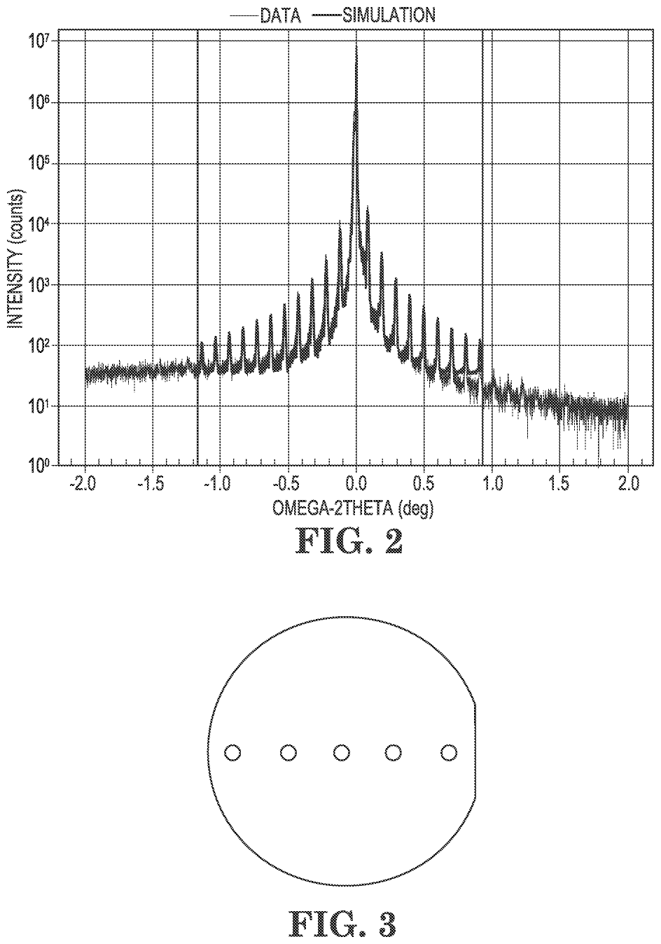

Referring now to FIGS. 2 and 3, embodiments of an MBE system configured for adjustable height between the substrate(s) and source(s) are described.

Uniformity of epitaxially grown films, both in terms of thickness and composition, can be of great importance to film integrity, device performance, and process yield. The thickness and compositional uniformity of films grown by molecular beam epitaxy (MBE) depends largely on the nature of the flux arriving from the sources, whether effusion cell, valved cracker, plasma, or otherwise. The flux plume that emerges from the sources is in general not collimated, but divergent, therefore the cross-section of flux incident on the platen surface is not translationally invariant in the vertical direction.

In various embodiments, non-uniformity of the flux incident on the platen surface can be reduced to near zero, for a rotating platen, by optimizing the height of the platen (substrate(s)) with respect to the sources. The impact of vertical substrate position on film thickness and compositional uniformity, may be used to determine the optimum substrate vertical position for different epitaxially grown materials, such as GaAs and AlAs.

In one embodiment, the behavior of Ga flux as a function of substrate-to-source working distance was determined. One of the applicant's commercially-available processing chambers was equipped with a vertically movable substrate similar to that shown in FIG. 1A. A characterization structure consisting of an 8-period InGaAs/GaAs Superlattice was chosen to provide straightforward film thickness results via X-ray diffraction measurements. Growth rate was determined by the spacing of superlattice-associated peaks in the XRD scans. XRD analysis was performed on five equally-spaced points, as represented by FIG. 3, across 100 mm GaAs wafers (4×100 mm platen) to obtain the flux profile.

In one embodiment, an MBE system was built for the purpose of testing the impact of changing the vertical position of the substrate/platen with respect to the sources. The movable carriage (hereinafter “CAR”) as shown in FIG. 1A utilized a programmable motor 112 and bellows 110 to allow for translation of the platen/substrate relative to the source(s) while maintaining Ultra-High Vacuum during a growth run after epitaxy begins. In various embodiments, the position of the substrate can set through the MBE system control software as a manual input or as an automated set of inputs via a recipe based on control parameters including measurements and/or timings. The epitaxial structures produced in this example were specifically designed to allow for precise characterization and clear understanding of film uniformity as shown in FIG. 2.

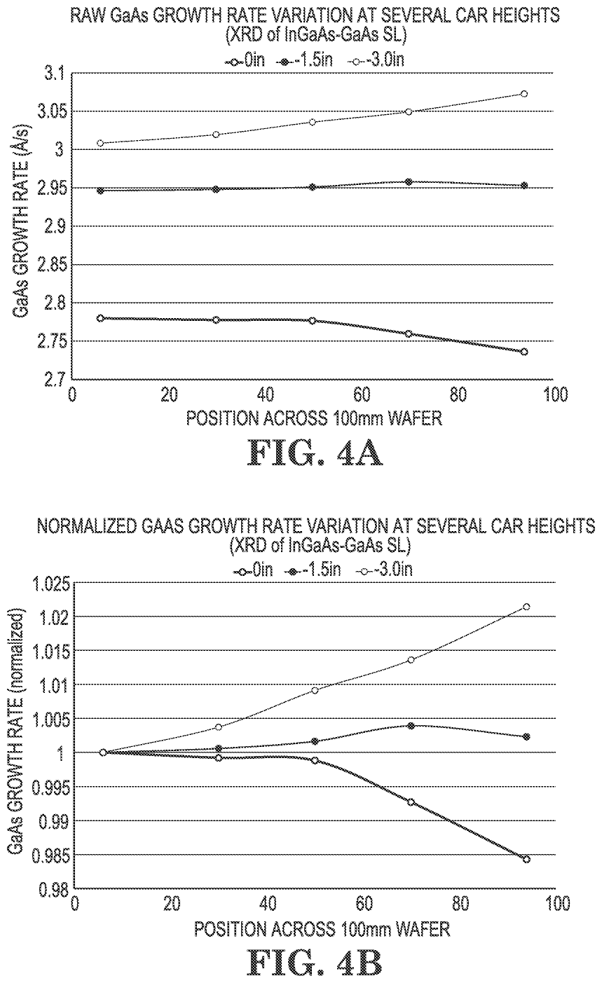

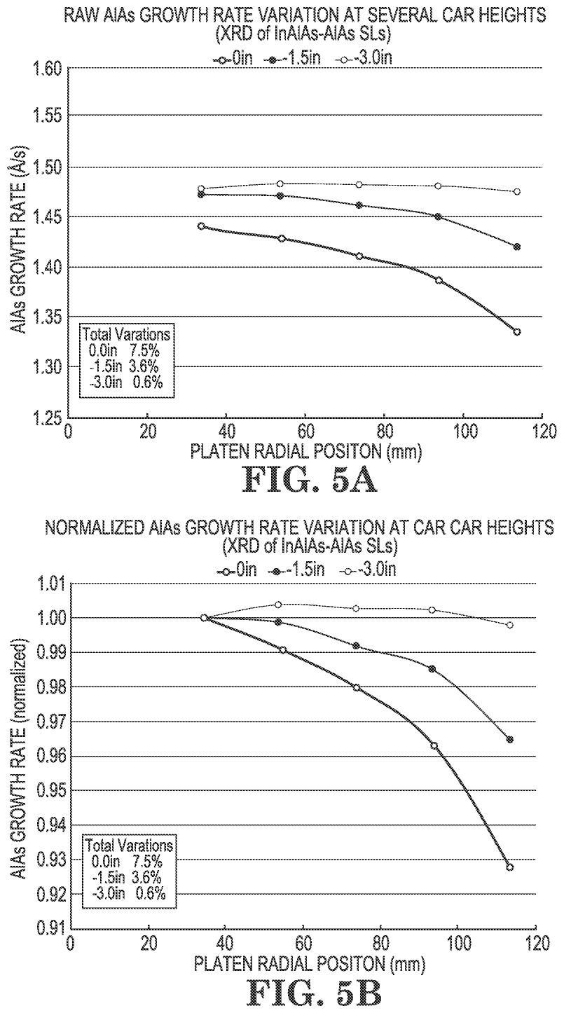

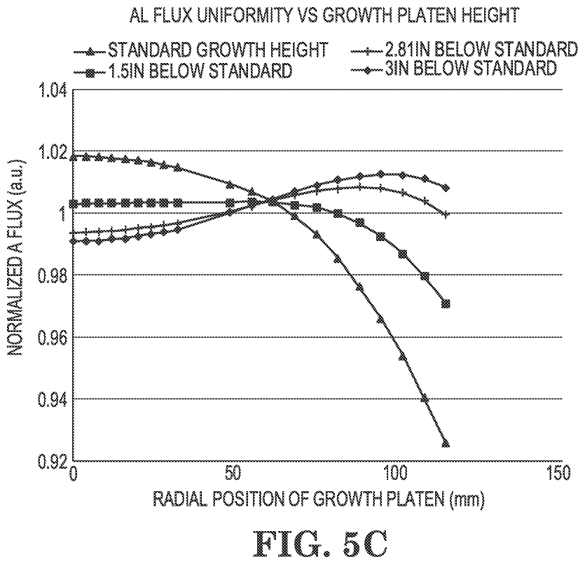

The measurements recorded for growth rate variation and normalized growth rate variation at different relative heights between the substrate(s) and source(s) are shown for GaAs in FIGS. 4A-4B, and for AlAs in FIGS. 5A-5B. For GaAs, the growths were performed at three different CAR positions:
Standard commercially available system position from VEECO INSTRUMENTS®
1.5 inches below standard
3.0 inches below standard

For GaAs as shown in FIG. 4A, the total growth rate variation for each growth run, defined as (maximum-minimum)/average, was found to be:
Standard height: ±0.79%
1.5 inches lower: ±0.19%
3.0 inches lower: ±1.06%

As shown in FIG. 4B, the normalized chart, the 1.5 in below standard line has the best uniformity.

It can therefore be said that it is typically For AlAs, the growths were performed at three different CAR positions:
Standard GEN200 system position
1.5 inches below standard
3.0 inches below standard

The total growth rate variation for each growth run, defined as (maximum-minimum)/average, was found to be:
Standard height: ±7.5%
1.5 inches lower: ±3.6%
3.0 inches lower: ±0.6%

The total growth rate variation for each growth run, defined as (maximum-minimum)/average, was found to be:
Standard height: ±7.5%
1.5 inches lower: ±3.6%
3.0 inches lower: ±0.6%

As shown in the chart of normalized thicknesses in FIG. 5B, the best overall thickness uniformity is accomplished at a distance of 3 inches below the standard CAR height. Notably, this is different than an optimum vertical position for GaAs (−1.5 inches from standard CAR height). With additional materials, still further height differences may be needed to improve thickness uniformity to desired levels.

Changing the source-to-substrate distance can have a drastic impact on both film growth rate and thickness uniformity. In various embodiments, it is possible to optimize the vertical position of the substrate to achieve excellent film thickness uniformity, demonstrated as better than ±0.2%. With respect to film thickness uniformity, the optimum vertical substrate position may be different for different epitaxial films. As shown in these examples, the optimum vertical substrate position for film thickness uniformity was shown to be different for GaAs and AlAs.

FIG. 5C shows a similar chart for the flux uniformity based on growth platen height for aluminum. As shown in FIG. 5C, the normalized flux changes such that at more displacement below standard, the radially outer portions of the platen grow faster relative to the standard growth height. There is an appropriate distance below standard position, therefore, where the flux across the radial position is roughly constant—in this case, 2.81 inches below standard is the closest possible to flat.

In other embodiments, the optimum vertical substrate position for film thickness uniformity for alloyed materials, for example, alloys of GaAs and AlAs such as Al0.5Ga0.5As, may be different than the optimum vertical substrate position for the binary constituents contained in the alloy. Likewise, the optimum vertical substrate position for film thickness uniformity for alloyed materials may be different than the optimum vertical substrate position for film thickness uniformity for the same alloyed material. That is to say, the vertical substrate position at which the composition of an alloy such as Al0.5Ga0.5As is most uniform may not be the same vertical substrate position at which the thickness of Al0.5Ga0.5As is most uniform.

Because many compound semiconductor devices grown by MBE consist of numerous layers containing different materials, in some embodiments the MBE system can be configured such that the substrate vertical position of the CAR can be dynamically adjusted in “real-time” during a growth run after epitaxy begins; in other words, adjusted through a growth recipe so that each layer can be grown at its uniquely optimum substrate position.

Referring to FIG. 6A, a schematic version of an embodiment of an MBE system in accordance with the present disclosure shows a first source and a second source positioned below a substrate and configured at an angle relative to the normal of the substrate such that the corresponding first beampath and second beampath intersect within the chamber as the evaporated material is directed to the substrate. A vertically adjustable arrangement that includes a bellow 110 and a motor 112 configured in this embodiment to dynamically vary a vertical position of the substrate/platen in a translation direction (Z) to effect a change in the height/distance between the substrate(s) and the source(s) during a growth run after epitaxy begins.

It should be understood that, in alternative embodiments, the bellow and motor combination can be replaced with other structures that ensure that the substrate remains level while being raised or lowered during processing. It has been recognized that due the difference in pressure between the interior and exterior of the process chamber, ensuring that the stage on which the substrate or other target is positioned remains level can present a technical challenge. If the vertical drive is accomplished with a force only on one side, the stage could become uneven and cause thickness nonconformity during processing. In one embodiment a z-drive that maintains level could be a ball-screw drive (as shown in FIG. 1A), or alternatively the stage could be raised or lowered using rack-and-pinion gear drive, pneumatic drive, a magnetic drive from outside the chamber, or a lever drive, among others.

FIG. 6B shows a depiction of the MBE system in accordance with an embodiment in which the vertically adjustable arrangement positions the substrate platen in the standard growth position. The blue origin symbol shows the standard growth center position. The center of the flux from the source is aiming at the very center of the substrate/platen.

FIG. 6C shows a depiction of the MBE system in accordance with an embodiment in which the vertically adjustable arrangement dynamically positions the substrate platen lowered 1.5″ from standard growth position during a growth run after epitaxy begins. The blue origin symbol shows the standard growth position. The center of the flux is now aiming off-center and the substrate is also closer to the source.

FIG. 6D shows a depiction of the MBE system in accordance with an embodiment in which the vertically adjustable arrangement dynamically positions the substrate platen lowered 3.0″ from standard growth position during a growth run after epitaxy begins. The blue origin symbol shows the standard growth position. The center of the flux is now aiming off-center and the substrate is still closer to the source than in FIG. 6C.

FIG. 6E is a detailed view of a vertical-shift mechanism suitable for use in a MBE system according to an embodiment.

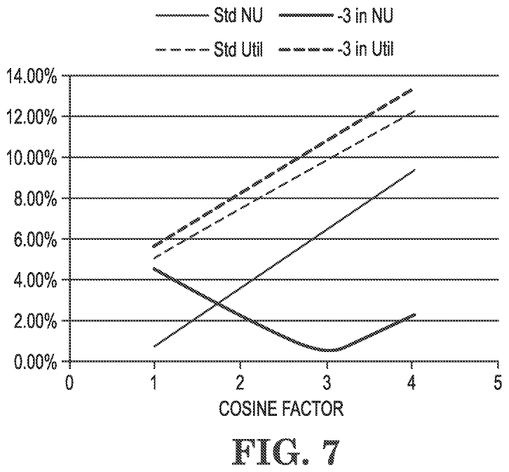

Referring now to FIG. 7, MBE source flux profiles can be modeled using simplified cos\hat{ }n(theta) flux shapes where theta is the angle relative to the axis of the orifice and n is based on the shape and style of crucible. Typically n falls between 1 and 3 but can be larger or smaller. Larger n values equate to “more focused” flux profiles and therefore are more desirable as they tend to have higher utilizations.

Existing MBE systems are rigid in that the source locations relative to the substrate are fixed before epitaxy begins for a given growth run. The angle of the source relative to the substrate is based on the chamber weldment. Prior to beginning epitaxy for a given growth run, the distance from the end of the source to the substrate can be manually varied in existing MBE system by changing the length of the source and/or pulling the source back using adapter nipples or physically pulling the sources back. This can be somewhat effective in increasing uniformity to a degree for the entire growth run after epitaxy begins, but that improvement in uniformity comes at the expense of using more source material per layer thickness grown for every layer during the growth run. In general the utilization changes by the square of the ratio of the source-to-substrate distance. For example, if the source-to-substrate distance is increased by a factor of 2, the utilization drops by a factor of 4.

### Retrofit Kits

Processing chambers can be large, highly sensitive pieces of equipment that are used almost continuously once installed. The systems and methods described herein related to the movement of the stage in the vertical direction can be accomplished not just on new systems, but indeed as a retrofit or improvement to existing systems.

According to a first embodiment, a kit can be provided when the existing heater uniformity is adequate to support the more complex vertical-shift assembly. In this first kit embodiment, a vertical shift manipulator assembly is provided as described above, capable of moving the stage closer to or further from the source material(s). The heater may need to be modified slightly to fit the new, vertical-shift manipulator. The kit further includes motor controllers, depending on the age and type of controllers in the existing system, to support the added functionality of the vertical shifting. The kit may include further gaskets, bolts, fasteners, or other hardware necessary to attach the vertical manipulator to the existing system.

Along with the physical components of the kit, software upgrades may be required to use the vertical manipulator. In embodiments, the kit can include software that can be programmed for the sequential deposition of multiple layers of different material. The software is configured to control the motors, actuators, heaters, and controllers of the existing systems and retrofit components to deposit each layer in processing conditions that are suitable for producing desired low levels of thickness non-uniformity.

In some systems, the temperature uniformity of the retrofit system may not be set up appropriately for vertical shift manipulation. This could be the case where, for example, the heater is designed to create a particular temperature at a very specific height based on where it assumes the target will always be. In a second kit embodiment, therefore, the kit can further include a new heater assembly with a sufficiently large diameter to provide targeted heating. In such embodiments, an upper cryopanel assembly may also be provided to support the insertion of the large heater.

### Crucibles

Because the source angles are fixed in MBE systems, changing the aiming point on the substrate is not typically possible. Instead of trying to directly change the source angle, various embodiments of the present disclosure are configured to dynamically lower the substrate, relative to its standard position during a growth run after epitaxy begins in order to change both the aiming position of the sources and the source-to-substrate distance. Modeling was performed using several n factors to determine the amount of lowering of the height/distance between the source(s) and substrate(s) necessary to improve the uniformity in various embodiments. Because the exact n is not known for each crucible, modeling was performed while varying the n to see what impact this might have.

For the GEN2000 MBE system (nominally 45° source tilt, 32″ source-to-substrate distance), it was modeled used VEECO INSTRUMENTS®'s proprietary software that lowering the substrate ˜4.75″ resulted in an order of magnitude improvement in the non-uniformity for an n of 2.6. Referring now to FIGS. 8A-8C, the results of this modeling of these embodiments for different configurations of the GEN2000 MBE system with different crucible designs and materials will be described. Furthermore, as described above with respect to FIG. 1H, the source can be tilted relative to this nominal 45° angle. It has been found that in a modification to existing systems, adjustments of up to 11° are possible without modifying the structure of the reactor itself.

FIG. 8A is a cross-section of the 10,000 g SUMO crucible commonly used for gallium and indium in the GEN2000. FIG. 8B is an improved, asymmetric SUMO crucible commonly used for gallium and indium in the GEN2000. FIG. 8C is the 3000 g-Al SUMO crucible commonly used for aluminum in the GEN2000 (location of additional heat shielding shown in red). Additional details regarding the design and operation of various embodiments of a crucible design are described in U.S. Pat. No. 5,820,681, the disclosure of which is hereby incorporated by reference.

The flux shapes are different from different crucibles and sources. For many reasons the crucible and diffuser plates used on different materials give slightly different flux patterns. To get better uniformity some sources need to be further away from the substrate (pulled back). When this happens the amount of material that hits the substrate is reduced. This reduces the utilization of the material which then requires a larger crucible or a shorter growth campaign. Having a better utilization of material is always better. In embodiments, a crucible for the GEN2000 that takes advantage of the better uniformity by aiming at the near side of the platen (7×6″ configuration) without having to change the system geometry.

In various embodiments, two crucibles were designed for the 3000 g Al SUMO source for the GEN2000. The first design utilizes a tilted orifice similar to that used in the 10 kg Ga SUMO source (see, e.g., FIG. 1H). The second designed uses a resized orifice based on feedback from the GEN200 platform.

### Materials

In various embodiments, optimized solutions may be based on the material being deposited. What works well for one material, may not work well for other materials. Things that influence the optimal source design include vapor pressure of the material, melting point, whether the material reacts or wets the crucible, thermal conductively of the material, size/shape/form of the material available, etc. Pyrolytic boron nitride (pBN) crucibles are commonly used for many materials in MBE (e.q. Group III materials in III/V semiconductors). These crucible work extremely well for gallium and indium where the sources can be run “hot lip” to prevent condensation and therefore have predictable flux profiles. However, using the same crucible shape for aluminum (for example) is not possible as aluminum reacts/wets the pBN surface and the liquid aluminum “creeps” to the hotter lip and can actually escape the crucible and destroy the effusion cell filaments. In embodiments, specific crucible shapes and heat shielding arrangements are designed and utilized to mitigate this wetting/creeping behavior. This crucible shapes, however, have different flux profiles, and therefore impact the composition of the grown layers.

Higher vapor-pressure materials benefit from smaller openings to increase the back-pressure inside the crucible. However, the smaller openings make it more difficult to load. In various embodiments, inserts for SUMO crucibles that allow for a larger opening for loading, with a smaller opening to restrict the flux. Each of the crucible configurations shown above (not an exhaustive sample set) would have a different flux profile (“n”) and therefore would have a different optimal substrate height to obtain optimal uniformity.

In addition to the improvement in non-uniformity by dynamically lowering the substrate during a growth run, the utilization and/or growth rate can be increased due to the slightly shorter source-to-substrate distance.

Depending upon the structure being grown, the operator (or reactor program) can independently modify process conditions to result in a desired level of thickness uniformity. For example, in a construction of AlAs wafer, the system may be operated 1.5 inches below standard height for gallium and 2.81 inches below standard height for aluminum. Generally, modeling has accurately predicted that significant improvements could be made to the flux profiles across the deposition platen. These models showed that uniformities would not suffer from decreases in thickness around the outer edge of the platen compared to standard operating conditions. Similarly, modeling predicted that all deposition rates would increase as the growth height of the platen was lowered. This proved to be true for Ga, but Al showed the opposite trend. It was surprisingly found, therefore, that there is a benefit to higher target height for aluminum that is not present for other materials. That is, the rate of usage of the source material can be affected by placing the target at different heights.

In some cases preferred locations of the substrate for purposes of use rate of the source material coincide with ideal placement for thickness uniformity. In other cases, however, achieving improved thickness uniformity can come at the cost of decreased efficiency in usage of the source material. To the extent that there is a conflict between these goals, users of the system may decide based on the needs of each wafer that is grown which of these factors is important, and which one to prioritize.

In certain embodiments, an underlying assumption is that the Al SUMO crucible functions in the same way as the Ga SUMO crucible; that is, the pressure in the crucible is high enough that beam self-scattering occurs in and near the mouth of the crucible. Data recently provided for a GEN200 MBE system demonstrates the pressure in the GEN200 Al crucible is lower than expected, such that beam self-scattering is not occurring at low deposition rates. In order to test the underlying theory. In some embodiments, it may be beneficial to examine Al flux uniformity as a function of rate or crucible fill for the GEN2000.

For solid or liquid source effusion cells used in MBE, the shape of the crucible has a significant effect on the uniformity of the flux or the shape of the flux plume from the source. Typically, for these types of conventional solid or liquid effusion sources, the crucibles can be classified as being either conical shaped, straight-walled, or complex shapes with negative gradient regions such as Veeco's proprietary SUMO crucibles.

For conical crucibles, the flux plume can, to first order, be thought of as simply evaporating or sublimating from the material surface and the shape of the plume being limited by the conical walls of the crucible. At the deposition rates that are practical to MBE, there are practically no interactions between atoms or molecules that evaporate from the material surface due to the inherently low pressure and long mean free path at practical vacuum conditions. For straight-walled crucibles, the flux similarly evaporates or sublimates from the material surface. However, in this case, there is more interaction with the walls of the crucible, as the material may bounce or scatter from the crucible walls a small number times before exiting the orifice of the crucible. In this way, straight-walled crucibles produce a more columnated flux plume that also changes shape as the material in the crucible depletes over time.

In complex-shaped crucibles, such as Veeco's proprietary SUMO crucibles, either some form of mechanical orifice is used or and negative gradient region in the wall of the crucible is used to create a restrictive orifice. The orifice results in back-scattering of the evaporated material and possibly some degree of compression of the atoms and molecules in the gas phase behind the orifice after evaporating or sublimating from the source material surface. In these more complex designs the shape of the flux plume, and the uniformity obtained at the MBE surface, is the consequence of a much more complicated interaction of (a) the gas with the crucible walls behind the orifice, (b) the gas with the orifice itself, (c) the gas with the shape of any conical section after the orifice (if present), and (d) the gas with itself due to self-scattering both inside the crucible body, the orifice, and possibly in the free space region just beyond the orifice. The advantages of these complex crucible shapes include the ability to engineer the shape of the crucible to improve the uniformity of the deposited material on the MBE growth surface as well as improving the utilization of the source material by minimizing the overspray. Additionally, when operated at conditions that promote significant gas-phase interactions, there is very little change the uniformity as the material in the crucible depletes.

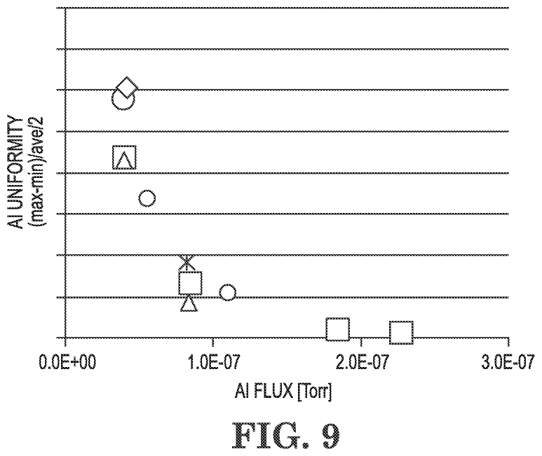

However, with complex crucible shapes, it is necessary to operate at conditions that promote gas phase interactions to achieve these benefits. In MBE growth, it is not always practical to operate in this way, and it is often necessary to operate an effusion cells both at higher and lower flux rates for different devices or different layers within a device. At lower flux rates, these gas phase interactions are reduced due to the lower pressure, and longer mean free path, inside the crucible and near the orifice region. As shown in FIG. 9 for an Al flux from a SUMO crucible, the uniformity observed at the growth surface can decrease rapidly for reduced fluxes.

In various embodiments, the method of dynamically adjusting the growth height in real time allows a new methodology for compensating for this variation in the growth uniformity as a function of the flux rate. Using this, for lower deposition rates that have inherently less uniform flux plumes, it will be possible to adjust growth height to optimize for each deposition rate separately. Importantly, the optimization is not necessary an optimization for only alloy layer compositional uniformity. Depending on the device structure, it might be more important to optimize for other things such as alloy layer thickness, effective dielectric constant of a layer, alloy layer optical thickness, or the total optical thickness of some number of nearest neighbor layers.

The use of graded fluxes, or fluxes that change rapidly in time, is commonly used and are very beneficial for many semiconductor devices. A number of these include the following:
Using alloy compositional grading in polar materials, such as AlGaN, to establish built-in electric polarization fields to force charge redistribution in semiconductor devices. This can be used to facilitate the formation of a 2D electron gas in high electron mobility transistors (HEMTs) or to artificially create high concentrations of electrons or holes that may not be achievable through conventional semiconductor doping.
Compositionally graded layers can be used to improve the current transport through doped barrier structures such as distributed Bragg reflectors (DBRs), thereby reducing resistive heating to facilitate higher power operation of devices such as lasers and LEDs.
Graded compositional layers can be used to tailor the design of the band structure in devices such as heterojunction bipolar transistors. In particular, this is necessary to either increase or decrease the energy or voltage offsets at specific layer interfaces to either increase or decrease as desired the conduction of charge across interfaces, or to make the conduction of one type of charge (electrons or holes) preferential over other.
In certain laser and LED devices, graded-index separate-confinement heterostructures (GrInSCH) layers, based on graded alloy layers, are commonly used to improve confinement of electrons and holes to quantum wells, and to improve the confinement of photons to the active gain region. This allows increased output power (for the same device thermal operational load), or increased device efficiency; this also results in improvements to device lifetime for given output power.

In various embodiments, the method of using dynamic adjustment of the growth height provides a new methodology to take advantage of the inherent plume shape differences between materials such as Ga, In, and Al to effect deposition rate grading as opposed to using thermal ramping of the sources. This method may be used independently or in conjunction with conventional thermal grading to achieve more complex grading profiles, for example, exponential or parabolic instead of linear. Additionally, this new method in certain embodiments will be able to effect grading more quickly (both in terms of process time and device spatial profile) and more reproducibly than conventional thermal grading.

Additionally, this new method of dynamically adjusting the growth height position provides a new methodology to influence MBE growth kinetics which has not existed previously. For example, using real-time adjustable height position will allow for very rapid, non-thermal adjustment of growth rates for even simple, adsorption-limited binary materials such as GaAs. Using this method, it may now be possible to grow a thicker layer of material, and near the end of the layer deposition to increase the height of the growth position; this will thereby reduce the effective growth rate and shift the growth kinetics to promote smoothing of thicker layers. This is clearly advantageous to MBE growth as it allows sharper epitaxial interfaces without requiring growth stops, which both waste process time and result in the accumulation of contaminants from the background vacuum environment at critical epitaxial interfaces.

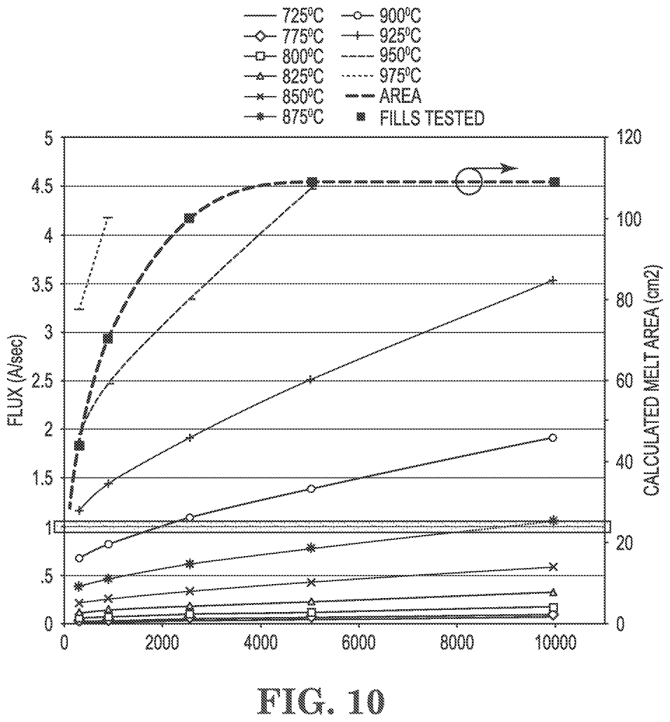

Referring now to FIG. 10, a depiction of embodiments that use the dynamically adjustable growth height is shown with respect to the growth mode, rate, and composition of materials deposited by molecular beam epitaxy (MBE) that may also be controlled via the temperature at which the effusion cells are operated. The operational effusion cell temperature is dependent on the vapor pressure of the material being evaporated. The usable flux produced by an effusion cell at a given temperature for any material being evaporated can be different for different melt volumes, melt shapes, and effusion cell geometry. The usable flux for materials evaporated in an effusion cell changes as that material is consumed. Therefore, the operational temperature of an effusion cell must be adjusted regularly to maintain a constant flux as material is depleted in the cell.

In various embodiments, an alternative method for maintaining a constant flux as source material is depleted is to adjust the substrate vertical position relative to the source. The effects of source depletion on the resulting effusion cell flux are shown in FIG. 10. Flux measurements were taken using EIES (electron impact emission spectroscopy) for different indium fill levels in a 10 kg SUMO source. The operating temperature for the cell had to be changed by more than 23° C. to maintain constant flux of 1 Å/s as the indium was depleted.

Theoretically, an MBE user could regularly adjust the position of the substrate via growth recipe to maintain a consistent growth rate throughout a growth campaign as source material is depleted. This would allow users to keep the cells at constant temperatures, eliminating the need for adjustments.

### Alternative Embodiments and Modifications

Various embodiments of systems, devices, and methods have been described herein. These embodiments are given only by way of example and are not intended to limit the scope of the claimed inventions. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the claimed inventions.

Persons of ordinary skill in the relevant arts will recognize that the subject matter hereof may comprise fewer features than illustrated in any individual embodiment described above. The embodiments described herein are not meant to be an exhaustive presentation of the ways in which the various features of the subject matter hereof may be combined. Accordingly, the embodiments are not mutually exclusive combinations of features; rather, the various embodiments can comprise a combination of different individual features selected from different individual embodiments, as understood by persons of ordinary skill in the art. Moreover, elements described with respect to one embodiment can be implemented in other embodiments even when not described in such embodiments unless otherwise noted.

Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims, it is expressly intended that the provisions of 35 U.S.C. § 112(f) are not to be invoked unless the specific terms “means for” or “step for” are recited in a claim.

1. A molecular beam epitaxy system comprising:
a process chamber defining a generally frustoconical volume that can support a high vacuum, the process chamber including:
a reactor base arranged at a bottom of the generally frustoconical volume and defining a plurality of ports proximate to the bottom, each of the plurality of ports configured to hold a source material that is heated to generate a plume of the source material; and
a platen arranged above the reactor base and configured to hold one or more wafer substrates; and
a vertical height manipulator coupled to the platen and configured to selectively move the platen to modify a distance between the platen and the reactor base.

2. The molecular beam epitaxy system of claim 0, wherein the vertical height manipulator is selected from the group consisting of a ball-screw drive, a rack-and-pinion gear drive, a pneumatic drive, a magnetic drive from outside the chamber, and a lever drive.

3. The molecular beam epitaxy system of claim 0, further comprising a controller.

4. The molecular beam epitaxy system of claim 0, wherein the controller is configured to modify the distance between the plurality of ports and the substrate based upon a particular material arranged in any one of the plurality of ports.

5. The molecular beam epitaxy system of claim 0, wherein the controller is configured to modify the distance between the plurality of ports and the substrate based upon a level of tilt of one of the plurality of ports.

6. The molecular beam epitaxy system of claim 0, wherein the controller is configured to modify the distance between the plurality of ports and the substrate during processing to create a wafer having a thickness non-uniformity of less than 1% across the wafer.

7. The molecular beam epitaxy system of claim 0, further comprising a plurality of crucibles, each of the plurality of crucibles arranged in a corresponding one of the plurality of ports and each of the crucibles containing one of the plurality of source materials.

8. The molecular beam epitaxy system of claim 0, wherein at least one of the plurality of crucibles is asymmetric.

9. The molecular beam epitaxy system of claim 0, wherein at least one of the plurality of crucibles is symmetric.

10. A kit for modifying a molecular beam epitaxy system, the kit comprising:
a vertical shift manipulator operably configured to couple a platen of the molecular beam epitaxy system such that the platen is arranged at a variable position to a reactor base within a processing reactor, the processing reactor subject to a high vacuum environment and including a plurality of ports, each of the ports having a corresponding source material;
at least one controllable motor configured to drive the vertical shift manipulator; and
software configured to control the controllable motor to create different variable distances for at least two of a plurality of layers generated by the molecular beam epitaxy system during sequential deposition of the plurality of layers.

11. The kit of claim 0, wherein the controller is configured to drive the controllable motor based upon a particular material arranged in a port of the molecular beam epitaxy system.

12. The kit of claim 0, wherein the controller is configured to drive the controllable motor based upon a level of tilt of one of a plurality of ports of the molecular beam epitaxy system.

13. The kit of claim 0, wherein the vertical height manipulator is selected from the group consisting of a ball-screw drive, a rack-and-pinion gear drive, a pneumatic drive, a magnetic drive from outside the chamber, and a lever drive.

14. The kit of claim 0, wherein the controller is configured to modify the distance between the plurality of ports and the substrate during processing to create a wafer having a thickness non-uniformity of less than 1% across the wafer.

15. The kit of claim 0, further comprising a replacement heater element.

16. The kit of claim 0, further comprising a cryolid having a cross-section larger than the replacement heater element.

17. A method for creating a wafer using a molecular beam epitaxy system, the method comprising:
arranging a substrate in the molecular beam epitaxy system such that the substrate is mechanically coupled to a vertical shift manipulator;
arranging a plurality of material sources in the molecular beam epitaxy system, the plurality of material sources corresponding to precursor materials of the wafer;
driving the substrate, with the vertical shift manipulator, to a predetermined distance from a first one of the plurality of material sources;
depositing a first layer of the wafer from the first one of the plurality of material sources at the substrate; and
repeating the driving and depositing for each of the plurality of material sources to form one or more additional layers of the wafer.

18. The method of claim 0, wherein the predetermined distance for each of the first layer and the one or more additional layers is set based upon a desired thickness uniformity of the wafer.

19. The method of claim 0, wherein the predetermined distance for each of the first layer and the one or more additional layers is set based upon a desired material usage efficiency for the plurality of precursor materials.

20. The method of claim 0, wherein the predetermined distance for each of the first layer and the one or more additional layers is set based upon both a desired thickness uniformity of the wafer and a desired material usage efficiency for the plurality of precursor materials.
